(19) United States
(12) Patent Application Publication
(10) Pub. No.: US 2009/0113166 A1
(43) Pub. Date: Apr. 30, 2009

(54) HASHING METHOD FOR NAND FLASH MEMORY

(75) Inventors: Alexandra Houston, Muenchen (DE); Martin Lohse, Gauting (DE); Thomas Ostendorf, Muenchen (DE); Sujoy Ray, Muenchen (DE); Kenneth Tuchman, Gronsdorf/Haar (DE)

Correspondence Address: MENDELSOHN & ASSOCIATES, P.C., 1500 JOHN F. KENNEDY BLVD., SUITE 405, PHILADELPHIA, PA, 19102, US

(73) Assignee: AGERE SYSTEMS INC., Allentown, PA (US)

(21) Appl. No.: 11/932,239

(22) Filed: Oct. 31, 2007

(51) Int. Cl. G06F 12/00; G11C 11/34; G11C 16/04

(52) U.S. Cl. 711/216; 365/185.17; 365/185.18

(57) ABSTRACT

In accordance with exemplary embodiments, a flash memory, such as a NAND flash memory, selectively updates blocks based on hash values associated with the blocks, wherein the hashing codes are generated for each block from the software image to be programmed into the flash memory. Selectively updating blocks in accordance with an embodiment of the present invention might reduce re-programming time and potentially destructive pre-mature aging of cells in the flash memory.

### BACKGROUND OF THE INVENTION

1. Field of the Invention

The present invention relates to memory circuits and, and, in particular, to re-programming in flash memory devices.

2. Description of the Related Art

Flash memory is non-volatile memory that can be electrically erased and re-programmed and is primarily used in memory cards and USB flash drives for general storage and transfer of data between computers and other digital products. Flash memory is a specific type of electrically erasable programmable read-only memory (EEPROM) that is programmed and erased in large blocks.

Flash memory stores information in an array of floating-gate transistors, called “cells”. In traditional single-level cell (SLC) devices, each cell stores only one bit of information. Multi-level cell (MLC) devices store more than one bit per cell by choosing between multiple levels of electrical charge to apply to the floating gates of its cells. Flash memory cells store data by storing charge within the flash cell as follows. During write operations, electrons are either injected into or withdrawn from the charge storage structure within the cell. The cell is primarily implemented with a MOSFET (metal-oxide-semiconductor field-effect transistor) transistor that has a threshold voltage proportional to the charge stored. If the MOSFET is an N-channel transistor, the larger the amount of negative charge stored, the higher the threshold voltage. If the MOSFET is a P-channel transistor, the larger the amount of negative charge stored, the lower the threshold voltage.

Two commonly employed types of flash memory technology are NOR gate flash memory and NAND gate flash memory. In NOR gate flash memory, each cell is a MOSFET transistor that has two gates instead of just one as in a standard MOSFET transistor. On top is the control gate (CG), as in other MOS transistors, but below CG is a floating gate (FG) insulated from its surroundings by an insulating oxide material. The FG sits between the CG and the MOSFET channel. Any electrons injected onto the FG are trapped and, under normal conditions, will not discharge for a period of many years because the FG is electrically isolated by the insulating material.

A single-level NOR flash cell in its default state is logically equivalent to a binary “1” value, because current will flow through the channel under application of an appropriate voltage to the control gate. A NOR flash cell is programmed to a binary “0” value by applying an elevated on-voltage to the CG (turning on the channel) so electrons can flow between the source and the drain. The source-drain current is sufficiently high to cause some high energy electrons to jump through the insulating layer onto the FG via a process called hot-electron injection. To erase a NOR flash cell (resetting it to the “1” state), a large voltage of the opposite polarity is applied between the CG and drain, pulling the electrons off the FG through quantum tunneling. NOR flash memory chips are divided into erase segments (often called blocks or sectors). The erase operation is performed on a block-wise basis: all the cells in an erase segment are erased together. Programming of NOR flash cells is generally performed one byte or word at a time.

While similar in structure and operation, NAND gate flash memory uses tunnel injection for writing and tunnel release for erasing. Tunnel injection is the quantum tunneling effect when charge carriers are injected to an electric conductor through a thin layer of an electric insulator (e.g., an insulating film). NAND flash memory employs a floating poly-silicon gate structure. The NAND flash memory device has a structure of strings, in which memory cells are connected with a single bit-line in series. The memory cell of a NAND flash memory has a MOSFET structure in which a floating gate and control gate (word line) are stacked, via an insulating film, on a semiconductor substrate serving as a channel region. A NAND cell is formed by serially connecting a plurality of memory cells while making adjacent memory cells share the source/drain. Charge is stored on a conductive poly-silicon gate that is entirely surrounded by dielectric material.

NAND flash memory forms the core of the removable USB interface storage devices known as USB flash drives, as well as most memory card formats available today. NOR flash memory has long erase and write times, but provides full address and data buses, allowing random access to any memory location. NAND flash memory exhibits faster erase and write times, requires a smaller chip area per cell, and has up to ten times the endurance of NOR flash memory. Consequently, NAND flash memory allows greater storage densities and lower costs per bit than NOR flash memory. However, the I/O interface of NAND flash memory does not provide a random-access external address bus. Data must be read on a block-wise basis, with typical block sizes of hundreds to thousands of bits.

NAND flash memories are accessed much like block devices such as hard disks. The pages are typically 512 or 2,048 bytes in size, and associated with each page are a few bytes (typically 12-16 bytes) used for storage of an error detection and correction checksum. The pages are typically arranged in blocks. A typical block would be 32 pages of 512 bytes or 64 pages of 2,048 bytes. The first page (page 0) is generally provided error-free, and a spare area of the first page is available to designers to include program code and associated data for block management. While programming is performed on a page basis, erasure is performed on a block basis.

NAND devices require bad block management to be performed by device driver software, or by a separate controller chip. When a logical block is accessed by high-level software, it is mapped to a physical block by the device driver or controller, and a number of blocks on the flash chip are set aside for storing mapping tables to deal with bad blocks. The error-correcting and detecting checksum will typically correct an error where one bit per 256 bytes is incorrect. When this happens, the block is marked bad in a logical block allocation table, and its undamaged contents are copied to a new block and the logical block allocation table is altered accordingly. If more than one bit in the memory is corrupted, then the contents are partly or completely lost.

In many applications, software programs are loaded into flash memory during manufacture of a consumer or other electronic device. During product development and production, or in service-center environments, such software programs might change, requiring the flash memory to be re-programmed several times with new software images. As this repetitive re-programming occurs, blocks can go bad causing pre-mature aging of flash memory cells. In addition, re-programming is a time-intensive activity in NAND flash memory.

### SUMMARY OF THE INVENTION

In one embodiment, the present invention allows for programming of flash memory by comparing, on a block-by-block basis, i) a hash value of a block of data of old software stored at a location in the flash memory with ii) a hash value of a block-aligned portion of new software for storage at the location of the block of data. If the hash value for the block-aligned portion and the hash value for the corresponding block of data stored in the flash memory are not equivalent, the block of data stored in the flash memory is re-programmed with the block-aligned portion;

In an alternative embodiment, the present invention allows for formatting program code embodied in tangible media to program flash memory by a) generating a binary image of the program code; b) generating block-aligned portions for the binary image, wherein the block-aligned portions correspond to blocks of data stored in the flash memory; (c) calculating, for each block-aligned portion, the corresponding hash value; and (d) inserting, into each block-aligned portion, the corresponding hash value.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a block diagram of an exemplary method of re-programming a NAND flash memory in accordance with an embodiment of the present invention;

FIG. 2 is an illustration for an exemplary format for a binary image converted in accordance with the method of FIG. 1; and

FIG. 3 shows an exemplary memory layout for a NAND flash memory employing an exemplary embodiment of the present invention.

### DETAILED DESCRIPTION

In accordance with exemplary embodiments of the present invention, a flash memory, such as a NAND flash memory, selectively updates blocks based on hash values associated with the blocks, wherein the hash values are generated for each block from the software image to be programmed into the flash memory. Selectively updating blocks in accordance with an embodiment of the present invention might reduce re-programming time and potentially destructive pre-mature aging of the memory's cells. While the exemplary embodiment is described herein with respect to NAND flash memory, one skilled in the art might extend the teachings herein to other types of re-programmable memory, such as NOR flash memory.

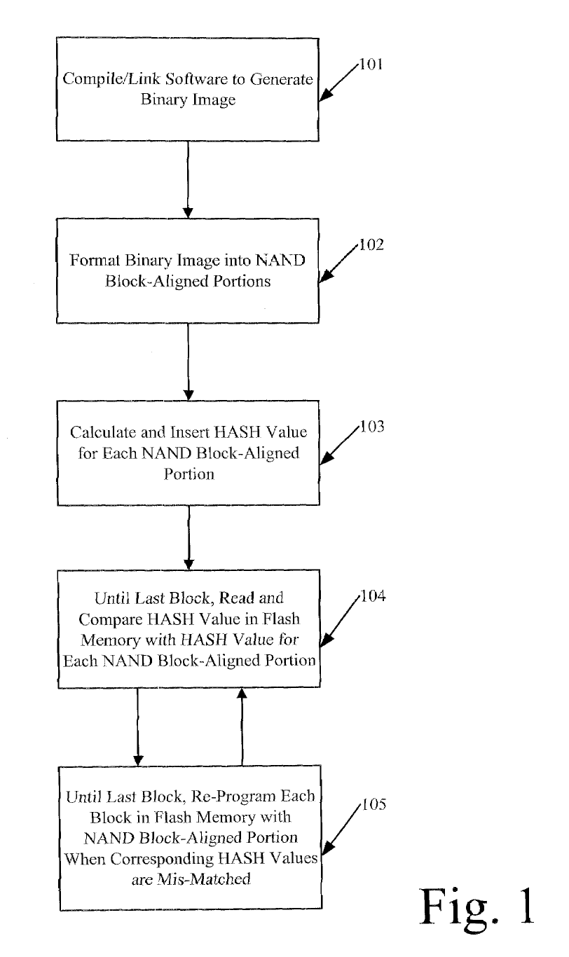

FIG. 1 shows a block diagram of an exemplary method of re-programming NAND flash memory in accordance with an embodiment of the present invention. At step 101, the new software (e.g., program code and associated data) to be programmed into the NAND flash memory is compiled/linked to produce a binary image of the software. At step 102, the binary image is pre-formatted by dividing the binary image into NAND block-aligned portions. NAND block-aligned portions are portions of the binary image data that correspond to blocks of data stored in a NAND flash memory based upon a predefined format for the NAND flash memory.

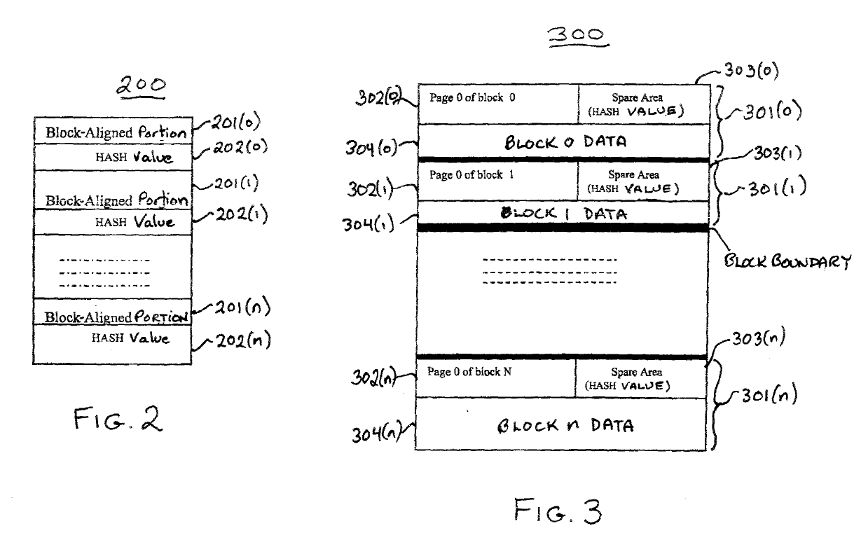

At step 103, a HASH value is calculated for, and incorporated into, each NAND block-aligned portion. FIG. 2 is an illustration of an exemplary format for a binary image 200 converted in accordance with step 103 of FIG. 1. As shown in FIG. 2, each of NAND block-aligned portion 201(0)-201(n) has a corresponding one of HASH values 202(0)-202(n) appended after the portion. Steps 101, 102, and 103 might typically be performed offline before flash devices are actually re-programmed with the software from which the binary image is produced.

As is well known in the art, a hash function is a reproducible method of turning a segment of data into a value having a relatively smaller number of bits compared to the original data segment, and this value serves as a digital fingerprint of the data segment. The hash function is an algorithm that substitutes and/or transposes the segments of data to create such fingerprints. The fingerprints are commonly referred to as hash sums, hash values, and hash codes. Hash values can be one-way (e.g., checksum, CRC, parity check, or Reed-Soloman values), where the hash value serves to identify errors in the data segment, or two-way, where the hash value not only identifies errors in the data segment but also allows for reconstruction of the original data segment.

Returning to FIG. 1, step 104 begins the process of re-programming a NAND flash memory. At step 104, the HASH values from the formatted binary image (e.g., as shown in FIG. 2) are read on a (NAND block-aligned) block-by-block basis and compared to corresponding HASH values stored in the NAND flash memory to be re-programmed. In accordance with the described exemplary embodiment, such HASH values stored in the NAND flash memory might be stored at page 0 of a NAND block. Page 0 might contain a spare area employed to store the HASH values, along with other error-correction and/or checksum information, program code, and other data. FIG. 3 shows an exemplary memory layout 300 for a NAND flash memory employing an exemplary embodiment of the present invention. As shown in FIG. 3, blocks 301(0) through 301(n) have corresponding PAGE 0s 302(0) through 302(n). Each of PAGE 0s 302(0) through 302(n), in turn, has an available area, shown in the figure as Spare Areas 303(1) through 303(n). The HASH value for each of blocks 301(0) through 301(n) is stored in the corresponding one of Spare Areas 303(0) through 303(n). Following each of PAGE 0s 302(0) through 302(n) is the corresponding block data, shown as block data 304(0) through 304(n).

Returning to FIG. 1, based on the block-by-block comparison of step 104, step 105 selectively updates blocks on a block-by-block basis based on hash values associated with the blocks. If the HASH value has not changed, the block is not re-programmed, and if the HASH value has changed (a mis-match), the complete NAND block is erased and re-programmed. Arrows are shown in FIG. 1 between steps 104 and 105 to indicate that the steps might be performed in sequence (i.e., all HASH value comparisons are made and then all NAND blocks having corresponding mismatched HASH values are re-programmed) or iteratively (i.e., a HASH value is read and compared for a current NAND block, the current NAND block is re-programmed if a mis-match in HASH values is present, and then the method advances to the next NAND block until all NAND blocks are checked and re-programmed as necessary).

The techniques described herein might significantly reduce software programming time, benefiting development, production, and service-center environments. In addition, employing the techniques herein might significantly increase the lifespan of NAND blocks within a NAND flash memory because only affected blocks are erased and re-written.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.” In addition, unless explicitly stated otherwise, each numerical value and range should be interpreted as being approximate as if the word “about” or “approximately” preceded the value of the value or range.

The present invention can be embodied in the form of methods and apparatuses for practicing those methods. The present invention can also be embodied in the form of program code embodied in tangible media, such as magnetic recording media, optical recording media, solid state memory, floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bitstream or other sequence of signal values electrically or optically transmitted through a medium, stored magnetic-field variations in a magnetic recording medium, etc., generated using a method and/or an apparatus of the present invention.

It should be understood that the steps of the exemplary methods set forth herein are not necessarily required to be performed in the order described, and the order of the steps of such methods should be understood to be merely exemplary. Likewise, additional steps may be included in such methods, and certain steps may be omitted or combined, in methods consistent with various embodiments of the present invention.

It will be further understood that various changes in the details, materials, and arrangements of the parts which have been described and illustrated in order to explain the nature of this invention may be made by those skilled in the art without departing from the scope of the invention as expressed in the following claims.

We claim:

1. A method of programming flash memory, the method comprising the steps of:
a) comparing, on a block-by-block basis, i) a hash value of a block of data of old software stored at a location in the flash memory with ii) a hash value of a block-aligned portion of new software for storage at the location of the block of data; and
if the hash value for the block-aligned portion and the hash value for the corresponding block of data stored in the flash memory are not equivalent;
b) re-programming the block of data stored in the flash memory with the block-aligned portion.

2. The invention of claim 1, wherein, for steps a) and b), each block-aligned portion corresponds to a portion of a binary image for program code corresponding to the new software.

3. The invention of claim 2, further comprising the steps of:
generating the binary image of the program code;
generating block-aligned portions for the binary image, wherein the block-aligned portions correspond to blocks of data stored in the flash memory;
calculating, for each block-aligned portion, the corresponding hash value; and
inserting, into each block-aligned portion, the corresponding hash value.

4. The invention of claim 1, wherein the method re-programs the flash memory with the new software.

5. The invention of claim 1, wherein, for steps a) and b), the flash memory is a NAND flash memory.

6. The invention of claim 5, wherein, for steps a) and b), the hash value for the block of data stored in memory is located at page 0 of the block.

7. A method of formatting program code embodied in tangible media to program flash memory, the method comprising the steps of:
a) generating a binary image of the program code;
b) generating block-aligned portions for the binary image, wherein the block-aligned portions correspond to blocks of data stored in the flash memory;
c) calculating, for each block-aligned portion, the corresponding hash value; and
d) inserting, into each block-aligned portion, the corresponding hash value.

8. The invention of claim 7, wherein, for step b), the flash memory is a NAND flash memory.

9. A machine-readable medium, having encoded thereon program code, wherein, when the program code is executed by a machine, the machine implements a method for programming flash memory, comprising the steps of:
a) comparing, on a block-by-block basis, i) a hash value of a block of data of old software stored at a location in the flash memory with ii) a hash value of a block-aligned portion of new software for storage at the location of the block of data; and
if the hash value for the block-aligned portion and the hash value for the corresponding block of data stored in the flash memory are not equivalent;
b) re-programming the block of data stored in the flash memory with the block-aligned portion.

10. The invention of claim 9, wherein, for steps a) and b), the flash memory is a NAND flash memory.
